(19) United States
(12) Patent Application Publication
(10) Pub. No.: US 2025/0322127 A1
(43) Pub. Date: Oct. 16, 2025

(54) Flexible Scaffold Chiplet Interconnect Systems and Methods

(71) Applicant: Altera Corporation, San Jose, CA (US)

(72) Inventors: Farhana Sheikh, Portland, OR (US); Harrison Liew, Portland, OR (US); Scott Weber, Piedmont, CA (US)

(21) Appl. No.: 19/251,044

(22) Filed: Jun. 26, 2025

(51) Int. Cl. G06F 30/32

(52) U.S. Cl. CPC G06F 30/32

(57) ABSTRACT

Systems or methods of the present disclosure may provide a compiler that generates a package layout for a multi-die package based on a common specification provided by a Flexible Scaffold Chiplet Interconnect (FlexSCI). The compiler may generate a scaffold interconnect network formed by a subset of interconnects provided by integrated circuits within the multi-die package. The compiler may also identify and/or assign a functionality to nodes of the scaffold interconnect network. The nodes may route data, verify and/or validate, and/or debug dies within the multi-die package. Then, the compiler may identify a position of each die within the scaffold interconnect network. The compiler may instruct a display to display the package layout and/or automatically implement the package layout on a multi-die package via a system design configuration. As such, the systems and methods of the present disclosure may simplify the design process for multi-die packages.

### BACKGROUND

The present disclosure relates generally to integrated circuits, such as processors and/or field-programmable gate arrays (FPGAs). More particularly, the present disclosure relates to designing and/or implementing a package layout on a multi-die package using a scaffold interconnect network (e.g., a Flexible Scaffold Chiplet Interconnect (FlexSCI) by Altera® Corporation).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Modern electronics, such as computers, portable devices, network routers, data centers, Internet-connected appliances, and more, tend to include at least one integrated circuit device. Integrated circuit devices may take on a variety of forms, including processors (e.g., central processing units (CPUs)), memory devices, and programmable devices (e.g., FPGAs), to name only a few examples. The programmable devices, in particular, may include a programmable fabric of logic that may be programmed (e.g., configured) and reprogrammed (e.g., reconfigured) after manufacturing to provide a wide variety of functionality based on a circuit design via a system design configuration. However, the various integrated circuit devices that are often included in a package with a programmable logic device may be manufactured by different vendors and/or implement different protocols for communication. As such, designing and implementing package layouts for the programmable devices may be difficult.

One or more programmable devices may be part of a multi-die package with other integrated circuits. It may be beneficial to test and/or validate the programmable devices within the multi-die package to verify functionality of each programmable device. However, as the size of and/or the number of components within the multi-die package increases, testing of the components within the multi-die package may be difficult. For example, the multi-die package may include a programmable device positioned between other integrated circuit devices, and accessing the programmable device for testing may be difficult. Furthermore, packaging technologies used by multi-die packages may include die-to-die (D2D) interconnects (e.g., connections) at pitches less than 10 microns (μm). As pitch size of the D2D interconnects decreases, an amount of space within the programmable devices may increase, thereby increasing the number of wires that may be disposed within the programmable devices and, furthermore, the number of wires available for D2D interconnects both horizontally (e.g., laterally) and vertically. This increase in wire density may facilitate an increase in design complexity since more interconnects may be available for data routing.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit system, in accordance with an embodiment of the present disclosure;

FIG. 2 is a block diagram of one example of the integrated circuit system of FIG. 1, in accordance with an embodiment of the present disclosure;

FIG. 3 is a schematic diagram of an example of the integrated circuit system of FIG. 1 including a scaffold interconnect network, in accordance with an embodiment of the present disclosure;

FIG. 4 is a schematic diagram of a process for designing and generating a package layout for the integrated circuit system of FIG. 1, in accordance with an embodiment of the present disclosure;

FIG. 5 is a flowchart of an example method for manufacturing the integrated circuit system of FIG. 1 with the scaffold interconnect network, in accordance with an embodiment of the present disclosure;

FIG. 6A is a schematic diagram of a node within the integrated circuit system of FIG. 1, where the node is formed by interconnects, in accordance with an embodiment of the present disclosure;

FIG. 6B is a schematic diagram of a node within the integrated circuit system of FIG. 1, where the node passively passes data, in accordance with an embodiment of the present disclosure;

FIG. 6C is a schematic diagram of a node within the integrated circuit system of FIG. 1, where the node includes a repeater and/or a retimer, in accordance with an embodiment of the present disclosure;

FIG. 6D is a schematic diagram of a node within the integrated circuit system of FIG. 1, where the node includes a protocol translator, in accordance with an embodiment of the present disclosure;

FIG. 6E is a schematic diagram of a node within the integrated circuit system of FIG. 1, where the node includes a communication interface, in accordance with an embodiment of the present disclosure;

FIG. 6F is a schematic diagram of a node within the integrated circuit system of FIG. 1, where the node includes security circuitry and a communication interface, in accordance with an embodiment of the present disclosure;

FIG. 6G is a schematic diagram of a node within the integrated circuit system of FIG. 1, where the node includes voltage regulator circuitry, in accordance with an embodiment of the present disclosure;

FIG. 7 is a flowchart of an example method for generating a package layout implemented onto the integrated circuit system of FIG. 1, in accordance with an embodiment of the present disclosure;

FIG. 8 is a schematic diagram of an example embodiment of an integrated circuit that facilitates protocol translation and may be within the integrated circuit system of FIG. 1, in accordance with an embodiment of the present disclosure;

FIG. 9 is a schematic diagram of an example embodiment of an integrated circuit that facilitates debugging operations and may be within the integrated circuit system of FIG. 1, in accordance with an embodiment of the present disclosure;

FIG. 10 is a schematic diagram of an example embodiment of an integrated circuit that may facilitate security operations, in accordance with an embodiment of the present disclosure; and

FIG. 11 is a block diagram of a data processing system including the integrated circuit system of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The present systems and techniques relate to embodiments for a scaffold interconnect network (e.g., a Flexible Scaffold Chiplet Interconnect (FlexSCI) by Altera® Corporation, a protocol-agnostic interconnect fabric, a flexible and/or scalable interconnect fabric, an interconnect network) that provides a common specification for designing a multi-chip package. The scaffold interconnect network may facilitate data routing (e.g., signal transfer) within an integrated circuit and/or between two or more integrated circuits within a multi-die package. The scaffold interconnect network may be formed based on dense wiring and/or nodes of one or more integrated circuit devices. The scaffold interconnect network may provide a network-on-package (NoP) that implements a desired system-in-package (SiP) out of the integrated circuit, interconnect physical layer (PHY) compatibility, and one or more additional functionalities, such as security operations, validation operations, and/or debugging operations, as described herein. For example, the scaffold interconnect network may include a first set of interconnects (e.g., scaffolds, interconnection scaffolds, wiring) of a first integrated circuit, a second set of interconnects on a second integrated circuit, a third set of interconnects on a package substrate, and so on. That is, the scaffold interconnect network may include structured wiring resources on different components within a multi-die package. The scaffold interconnect network may also include nodes that may be formed at an intersection of two or more interconnects. The nodes may be communication junctions for functional blocks (e.g., integrated circuits) within the package. For example, the node may facilitate signal transfer, perform different functionalities, and so on. In particular, an architecture and/or routing rules of the scaffold interconnect network may be provided as a standard to manufacturers of integrated circuits and simplify the design of multi-die packages for designers (e.g., a user). The positioning of the nodes is specified so that nodes of one integrated circuit align with nodes of another integrated circuit in the package. This allows for a more seamless design process that enables both experts and newer users alike to efficiently design multi-die packages.

With the foregoing in mind, the present systems and techniques also relate to embodiments of a compiler (e.g., a companion compiler) that leverages field-programmable gate array (FPGA)-like programmability and generator-based design techniques. For example, the compiler may receive a layout (e.g., connectivity graph) for the multi-die package and automatically generate a package layout that leverages the scaffold interconnect network. The connectivity graph may provide information (e.g., definitions) regarding each integrated circuit to be included in a multi-die package, such as a position and/or orientation of interconnects of the integrated circuits, positions of nodes of the integrated circuits, communication standards and/or protocols used by the integrated circuits, and so on. Based on the connectivity graph, the compiler may identify a “sea of wires” including the interconnects of the integrated circuits, divisions between each integrated circuit and/or each package, and so on. The “sea of wires” may include interconnects going laterally in every plane (e.g., integrated circuit, substrate, bridge) and vertically between the planes. The compiler may identify edges of the scaffold interconnect network based on the sea of wires. As used herein, an “edge” of the scaffold interconnect network may include a number of wires forming a bus that may be activated based on defined nodes and interconnect specifications (e.g., a functionality to be performed by the interconnects). The compiler may also identify and/or assign a functionality provided by one or more nodes, positions of activated nodes, and so on. The compiler may include a library of circuits that may be implemented by the scaffold interconnect network, such as nodes of the scaffold interconnect network, one or more integrated circuits of the multi-die package, and so on. By way of example, the circuits may include circuitry for debugging operations, security operations, routing operations, and so on. The compiler may assign a functionality to one or more nodes based on available functionalities in the library. Then, the compiler may generate and output a package layout for the multi-die package. For example, the compiler may instruct a display to display the package layout. In other examples, the compiler may provide the package layout to an implementation tool to implement the package layout onto a multi-die package. As such, the compiler may reduce design time and/or simplify the design process.

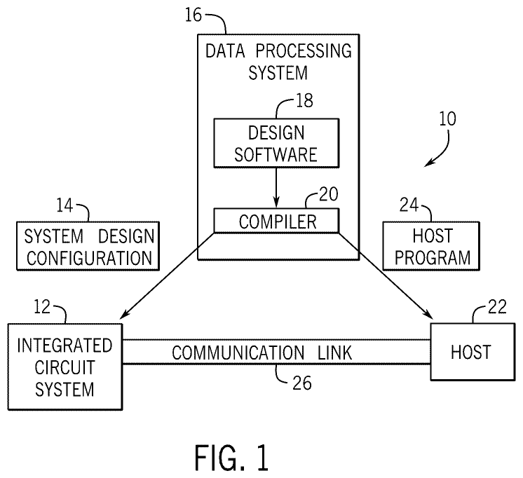

With the foregoing in mind, FIG. 1 illustrates a block diagram of a system 10 that may be used to program an integrated circuit system 12, such as an FPGA (e.g., Agilex™, Stratix®, Arria®, MAX®, or Cyclone® devices by Altera® Corporation), with a system design using a system design configuration 14. Note that, while this disclosure largely refers to the integrated circuit system 12 including programmable logic devices, such as an FPGA, in some embodiments, the integrated circuit system 12 may also include a one-time programmable device or structured application specific integrated circuit (ASIC), such as an Intel® eASIC™ device by Intel® Corporation. In other examples, the integrated circuit system 12 may include any suitable integrated circuit that is manufactured to have a particular system design with circuitry to perform desired data processing operations. The integrated circuit system 12 may include a single monolithic integrated circuit or a multi-die system of integrated circuits. The integrated circuit system 12 may include a single integrated circuit, multiple integrated circuits in a package, or multiple integrated circuits in multiple packages communicating remotely (e.g., via wires or traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit system 12. In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In a configuration mode of the integrated circuit system 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit system 12.

Additionally or alternatively, the host 22 running a host program 24 may control or implement the system design configuration 14 onto the integrated circuit system 12. For example, the host 22 may communicate instructions from the host program 24 to the integrated circuit system 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

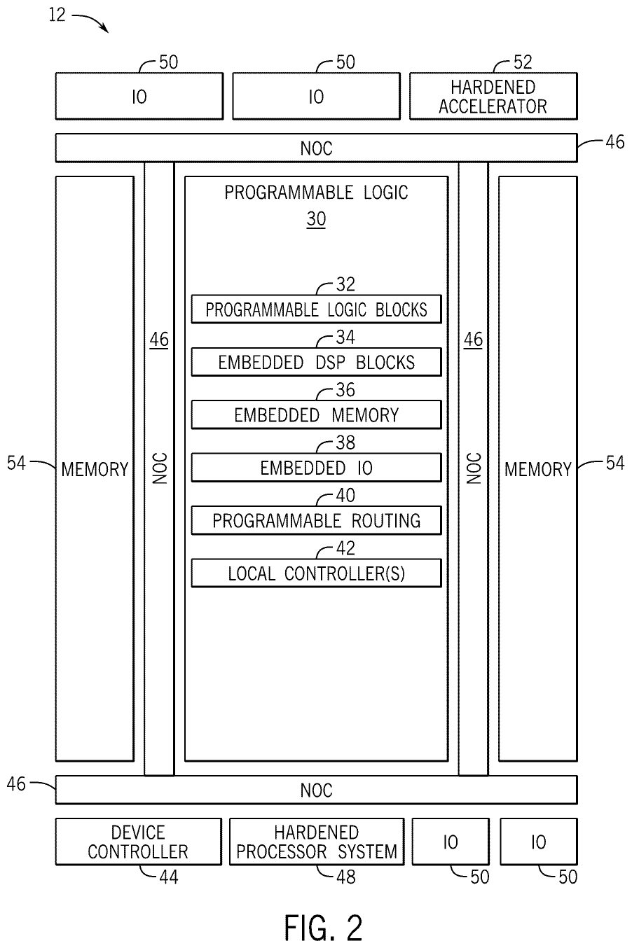

The integrated circuit system 12 may take any suitable form that may implement the system design configuration 14. In one example shown in FIG. 2, the integrated circuit system 12 may include programmable logic circuitry 30, which includes a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any of the programmable logic blocks 32 to implement any desired logic circuitry when programmed (e.g., configured) with the system design configuration 14. The programmable logic blocks 32 and are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 kB, blocks of 1 MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit system 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit system 12. The device controller 44 may include any suitable logic circuitry to control and/or program the programmable logic circuitry 30 or other elements of the integrated circuit system 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 44 may include a hardware finite state machine (FSM). The device controller 44 may provide other functions, such as serving as a platform for virtual machines that may manage the operation of the integrated circuit system 12.

A network-on-chip (NOC) 46 may connect the various elements of the integrated circuit system 12. The NOC 46 may provide rapid, packetized communication to and from the programmable logic circuitry 30 and other blocks, such as a hardened processor system 48, high-speed input-output (IO) blocks 50, a hardened accelerator 52, and local device memory 54. The integrated circuit system 12 may include the hardened processor system 48 when the integrated circuit system 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit system 12. The high-speed IO blocks 50 may enable communication using any suitable communication protocol(s) with other devices outside of the integrated circuit system 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

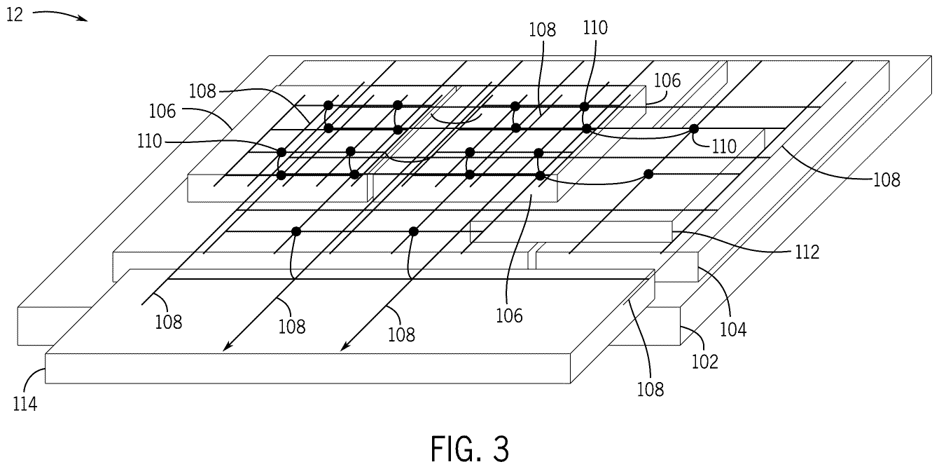

FIG. 3 is a schematic diagram of the integrated circuit system 12 as a multi-die package including a scaffold interconnect network 100. As illustrated, the integrated circuit system 12 may include a package substrate 102, base dies 104 (e.g., first dies) mounted on the package substrate 102, and top dies 106 (e.g., second dies) mounted on the base dies 104. The base dies 104 and/or the top dies 106 may include integrated circuits, FPGAs, ASICs, or any combination thereof. As illustrated, the integrated circuit system 12 may include two base dies 104 and two top dies 106, where the two top dies 106 may be mounted onto one of the base dies 104. The two base dies 104 may be positioned proximate to each other in a 2.5-dimensional (2.5D) form and route data between the dies via an interposer. The top dies 106 mounted on the base die 104 via microbumps in a 3-dimensional (3D) form. The base die 104 may route data between the two top dies 106. As such, the base die 104 may be an active interposer. It should be understood that the multi-die package of FIG. 3 is exemplary and that integrated circuit system 12 may include any suitable number of base dies 104 and/or top dies 106 in any suitable configuration.

The base dies 104 and/or the top dies 106 may each include a plurality of interconnects (e.g., a plurality of scaffolds, an interconnection scaffold) positioned on a surface of the dies, within the dies, or both. The interconnects may include wires with any suitable pitch size. Additionally, the interconnects may be positioned using any suitable spacing on the surface of the dies, within the dies, or both. For example, the interconnects may include fine-pitched wires with a pitch size of 10 microns (μm) or less. The positioning of the interconnects may be provided by a manufacturer of the base dies 104 and/or the top dies 106. For example, the manufacturer may follow a pattern, such as a pattern provided by FlexSCI, when determining a positioning of and/or a spacing between each interconnect. As such FlexSCI may provide guidelines for manufacturing integrated circuits that may be used in the integrated circuit system 12 along with the scaffold interconnect network.

During package compilation, a subset of the plurality of interconnects may be activated to perform operations during operation of the multi-die package. The activated interconnects may be referred to herein as “edges” of the scaffold interconnect network 100. For example, the edges may provide data transfer within the respective die and/or between the components of the multi-die package. one or more interconnects and/or one or more nodes 110. Additionally or alternatively, the edges may include a set of wires forming a bus that may be activated based on defined nodes and/or interconnect requirements of the multi-die package. The remaining interconnects may be suited for power meshes for connections to voltage regulator circuitry and/or structures for clock distribution, such as traveling wave and resonate clocks, and so on.

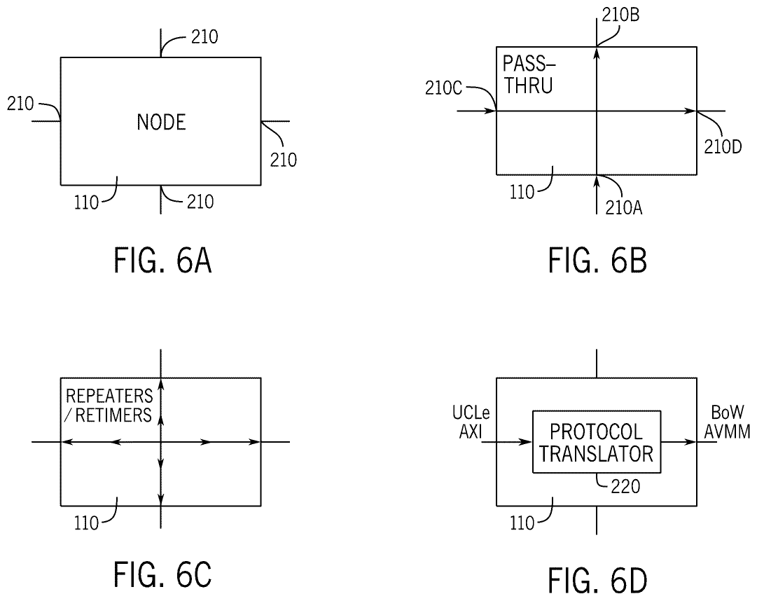

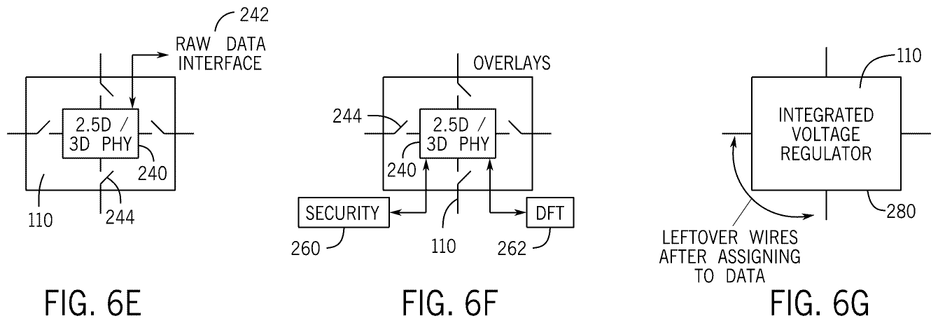

At the intersection of two or more interconnects, a node may be formed. In some examples, the positions and/or functionalities of the nodes may be provided by a manufacturer of the die (e.g., the base die 104, the top die 106). For example, the manufacturer may activate certain nodes of a die and/or may not activate certain nodes of the die. In other examples, the positions and/or functionalities implemented by the nodes may be determined during package compilation. The manufacturer may provide information regarding the activated nodes 110, a position and/or orientation of the activated nodes 110, and so on. The nodes 110 may be communication junctions for the base dies 104 and/or top dies 106. The nodes 110 may be scale-down interconnects, scale-out interconnects, adapters, switches, and so on. As further discussed with respect to FIGS. 6A-G, the nodes 110 may provide for different functionalities and/or perform different operations within the integrated circuit system 12. For example, the nodes 110 may include overlays (e.g., circuitry) that may otherwise be transparent to normal integrated circuit functionality.

As illustrated in FIG. 3, each die 104, 106 may include edges 108 in a horizontal direction and/or a vertical direction. The edges 108 may include on-die interconnects, which may be active interconnects. Additionally, each die 104, 106 may include nodes 110 at the intersection of the edges 108. As discussed herein, the top dies 106 may be mounted to the base die 104 via microbumps. The microbumps may provide 3D die-to-die (D2D) interconnects that may be activated as edges 108 of the scaffold interconnect network 100 and facilitate communication between the dies 104, 106. The microbumps may be used for interfacing with other integrated circuits within the same multi-die package. However, it should be understood that any suitable bonding techniques may be used to couple the top dies 106 to the base die 104, and the bonding technique may provide the 3D die-to-die (D2D) interconnects. The illustrated nodes 110 may include activated nodes, and it should be understood that the dies 104, 106 may include additional nodes that may not be activated. The nodes may be activated and/or deactivated by blowing a fuse, for example. In another example, the nodes may be activated in response to coupling to another component. That is, the nodes not coupled to other components may not be functional and/or perform any functions.

The base dies 104 and/or the top dies 106 may be mounted on a package substrate 112. The package substrate 112 may also include interconnects, such as in-package interconnects and/or 2.5D D2D interconnects. A subset of the interconnects may be activated to provide edges 108 of the scaffold interconnect network 100. The edges 108 may route data between the base dies 104, the top dies 106, and off-package components (e.g., components coupled to the package substrate 112 and outside of the integrated circuit system 12). The package substrate 112 may couple to one or more ball grid array (BGA) balls that facilitate signal transfer between components of the integrated circuit system 12. As such, the BGA balls may provide a number of interconnects that may form part of the scaffold interconnect network.

The integrated circuit system 12 may also include bridges 112 and 114. As illustrated, the integrated circuit system 12 may include an intra-package bridge 112 with interconnects (e.g., scaffolds, D2D scaffolds), such as 2.5D D2D interconnects, and an inter-package bridge 114 (e.g., a package-to-package bridge) with interconnects, such as 2.5D D2D interconnects, to route data between the dies 104, 106. The intra-package bridge 112 may include a silicon bridge (e.g., an embedded multi-die interconnect bridge (EMIB), an interposer) that routes data between the two base dies 104. The inter-package bridge 114 may route data between different packages that may also be mounted to the package substrate 102. The intra-package bridge 112 and/or the inter-package bridge 114 may include active interposers, passive interposers, bridges, or any combination thereof. The intra-package bridge 112 and/or the inter-package bridge 114 may also facilitate power delivery between the dies 104, 106 and/or between the one or more integrated circuit systems. To this end, a subset of the interconnects of the intra-package bridge 112 and a subset of the interconnects of the inter-package bridge 114 may be activated to form edges 108 of the scaffold interconnect network 100. The intra-package bridge 112 may be coupled to the package substrate 112 via package substrate bumps (PSBs) (e.g., package substrate build-ups, controlled collapse chip connection (C4) bumps). The PSBs may provide interconnects that facilitate communication between the two base dies 104 and the intra-package bridge 112. The microbumps may have any suitable size smaller than the PSBs. Generally, the PSBs (e.g., bumps used for interfacing with off-package components) are substantially larger than in size compared to microbumps (e.g., bumps or bonds used for interfacing with other chips (e.g., chiplets, dies) within the same multi-die package). The number of microbumps is also generally much greater than the number of PSBs (e.g., the ratio of the number of microbumps to the number of PSBs may be greater than 2:1, 5:1, 10:1, 100:1, 1000:1, 10,000:1, 100,000:1, and so forth).

As illustrated, the scaffold interconnect network 100 may be formed by the edges 108 of the base dies 104, the top dies 106, the intra-package bridge 112, the inter-package bridge 114, and the package substrate 102 as well as the nodes 110 of the base dies 104 and the top dies 106. For example, the edges 108 may include on-die interconnects of the base dies 104 and the top dies 106, the in-substrate interconnects or passive interconnects of the package substrate 102, 2.5D D2D interconnects of the intra-package bridge 112 and/or the inter-package bridge 114, and 3D D2D interconnects of the microbumps between the top dies 106 and the base die 104. At the die level, the scaffold interconnect network 100 facilitates communication within the die and may perform operations similar to a micro Network-on-Chip (μNOC). For example, a μNOC may facilitate data transfer within an integrated circuit, and a NOC may facilitate data transfer between components of the integrated circuit system 12. The scaffold interconnect network 100 may also facilitate communication between the components of the multi-die package and with other multi-die packages.

As components may be added and/or removed from the integrated circuit system 12, the scaffold interconnect network 100 may be adjusted. For example, a position of the interconnects and/or the nodes may be adjusted so that data may be routed throughout the integrated circuit system 12. Indeed, it should be understood that the scaffold interconnect network 100 may be formed by any suitable interconnects of any suitable number of components within the integrated circuit system 12. As such, the scaffold interconnect network 100 may provide a widely distributed, scalable scaffold interconnect network that uses a μNOC architecture at the die and active/passive substrate levels. Additionally, it should be understood that the integrated circuit system 12 may include fewer components or more components than described in the example of FIG. 3. For example, as more components may be added to the integrated circuit system 12, the interconnects of the added components may be activated as edges 108 of the scaffold interconnect network 100, thereby providing for a flexible and scalable network.

As further described herein, the scaffold interconnect network 100 may facilitate different operations within the multi-die package. For example, the scaffold interconnect network 100 may perform protocol translation to facilitate communication using different protocols and/or different standards. In other examples, the scaffold interconnect network 100 may facilitate security operations, testing and/or validation operations, debugging operations, and so on. For example, the operations may be performed by the nodes 110 of the scaffold interconnect network 100. As further described with respect to FIGS. 6A-G, the nodes 110 may include scale-down/scale-out interconnects, adapters, switches, protocol translators, validation circuitry, security circuitry, and the like. In another example, the operations may be performed by dies positioned within the multi-die package.

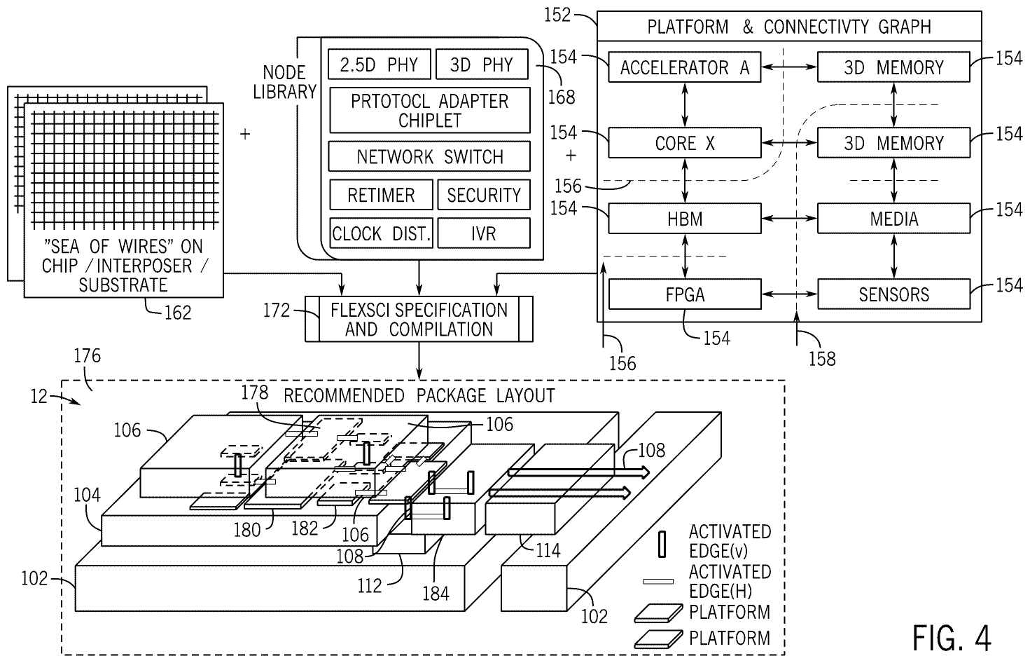

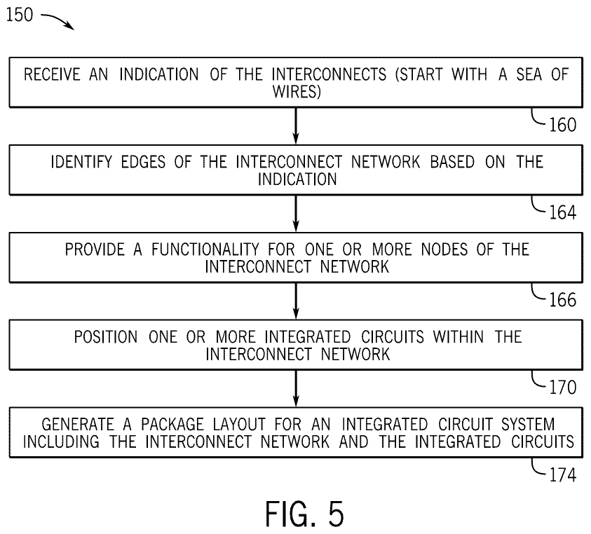

FIG. 4 illustrates a flow diagram for generating a package layout for the integrated circuit system 12 that includes the scaffold interconnect network 100. FIG. 5 is a flowchart of an example method 150 for generating a package layout for a multi-die package including the scaffold interconnect network 100. The method 150 may be performed by the compiler 20, the design software 18, processing circuitry of the data processing system 16, or any combination thereof. For brevity and clarity, the FIGS. 4 and 5 will be described together below.

During package compilation, the processing circuitry may receive information associated with components that may be used in the integrated circuit system 12. For example, a manufacturer and/or a vendor may provide a datasheet with specification information and/or definitions of a component, such as a die, a bridge, a substrate, and so on, that may be used within the integrated circuit system 12. The datasheet may be stored in a memory, a database, and/or a cloud server. The specification information may include connectivity information, such as position and/or orientation of the interconnects, a number of nodes 110, a position of the nodes 110, and/or a type of node 110 that may be activated on the integrated circuit, and so on.

The processing circuitry may receive a connectivity graph 152 indicative of the integrated circuit system 12. The connectivity graph 152 may provide a visual and/or structural representation of how different components within the integrated circuit system 12 may be organized and/or connected. The connectivity graph 152 may also indicate a number of components to include in the integrated circuit device. Additionally or alternatively, the connectivity graph 152 may provide definitions of each component to be in the integrated circuit system 12. The definitions may include a type of component, a functionality of the component, and so on. As illustrated, the connectivity graph 152 includes different components 154, such as an Accelerator A, a Core X, a 3D Memory, an artificial intelligence (AI)/machine learning (ML) circuitry, a media circuitry, sensor circuitry, a high bandwidth memory (HBM), and a FPGA, that may be included in the integrated circuit system 12. Using the connectivity graph 152, the processing circuitry may identify connections between the components 154. For example, the Accelerator A may be coupled to 3D memory and the Core X, or the sensors may be coupled to the FPGA and the media block.

The connectivity graph 152 may also provide splits between the components of the integrated circuit system 12 and/or between the different packages. That is, the compiler 20 may receive an indication of the splits as an input for generating the package layout. For example, the components may be split across different integrated circuits, different packages, and so on. As illustrated, the platform and connectivity graph 152 may include a first split line 156 indicative of splits between different integrated circuits and a second split line 158 indicative of splits between different packages. The first split line 156 may be indicated with a first color and the second split line 158 may be indicated with a second color that may be different from the first color. For example, the FPGA may be disposed within a first integrated circuit, the HBM may be disposed within a second integrated circuit, and the Accelerator A and the Core X may be disposed within a third integrated circuit. In another example, the AI/ML circuitry, the media circuitry, and the sensor circuitry may be disposed within a first multi-die package and the remaining components may be positioned within a second multi-die package.

At block 160, the processing circuitry may identify a plurality of interconnects (e.g., the “sea of wires”). The processing circuitry may retrieve specification information from a database, a memory, and/or a cloud server based on the connectivity graph 152. For example, the compiler 20 may identify product information associated with the first integrated circuit (e.g., implementing the FPGA), the second integrated circuit (e.g., implementing the HMB), the third integrated circuit (e.g., implementing the Accelerator A and the Core X), and so on. The processing circuitry may identify a position and/or orientation of the interconnects provided by each component based on the specification information. In other words, the compiler may identify a “sea of wires” 162 provided by each component of the integrated circuit system 12. Additionally or alternatively, the processing circuitry may retrieve specification information associated with a package substrate, one or more interposers and/or bridges, and the like, and the processing circuitry may identify a position and/or orientation of the interconnects provided by the components. As such, the compiler 20 may identify a “sea of wires” 162 that may be used to form the scaffold interconnect network 100.

At block 164, the processing circuitry may identify edges 108 of the scaffold interconnect network 1100 based on the indication. The edges may include N-set of wires that form a bus that may be activated based on activated nodes 110 and specifications of the nodes 110. For example, the compiler 20 may allocate a subset of interconnects of the plurality of interconnects as edges 108. The edges 108 may include any suitable number of interconnect bundles that may be configurable based on interconnect specifications. For example, the processing circuitry may identify edges 108 for 2.5D communication, 3D communication, D2D communication, off-package communication, and so on based a position and/or orientation of the interconnect, the platform and connectivity graph 152, the interconnect specifications, and so on. The subset of interconnects may form the edges 108 of the scaffold interconnect network 100. The remaining interconnects may not be activated for routing data but may be activated to perform other operations within the integrated circuit. In other embodiments, the remaining interconnects may not be coupled to any component within the integrated circuit and/or the integrated circuit system 12 and, thus, may not be activated to perform any operations. For example, the remaining interconnects may not be functional.

At block 166, the processing circuitry may provide a functionality for one or more nodes 110 of the scaffold interconnect network 100. For example, the processing circuitry may reference a library 168 (e.g., library of circuits) to identify one or more circuitries that may be implemented by respective nodes 110. As discussed herein, the library 168 may include different functionalities and corresponding system design configurations (e.g., configuration bitstreams) that may be implemented by the nodes 110. For example, the library 168 may include circuits corresponding to 2.5D PHY, 3D PHY, protocol adapters, switches, retimers, security operations, clock distance, voltage regulators, and so on. The circuits of the library 168 may also be implemented by integrated circuits, such as the base dies 104 and/or the top dies 106 discussed with respect to FIG. 3, that may be added to the integrated circuit system 12.

At block 170, the processing circuitry may position integrated circuits within the scaffold interconnect network 100. The processing circuitry may utilize guidelines (e.g., rules) provided by FlexSCI to generate the scaffold interconnect network 100. That is, FlexSCI may provide guidelines to define a “scaffold” graph structure, or the scaffold interconnect network 100, out of the sea of wires provided by the integrated circuits. As illustrated in FIG. 4, the integrated circuit system 12 may include the base dies 104 and the top dies 106 placed between the edges 108 and the nodes 110, thereby encompassing a section of the scaffold interconnect network 100. By way of example, the scaffold interconnect network 100 may be analogous to a scaffold of a building. The scaffold may provide a framework for the building and the components of the building may be positioned around the scaffold. Similarly, functional units that occupy silicon area (e.g., integrated circuits, substrates, bridges) may be analogous to the components of the building and positioned around the scaffold interconnect network 100. As such, the positions of the integrated circuits may be determined after the scaffold interconnect network 100 may be generated by the processing circuitry. The processing circuitry may also use the FlexSCI guidelines to determine connections between components within the integrated circuit system 12, position the integrated circuits within the scaffold interconnect network 100, and so on.

At block 174, the processing circuitry may generate a package layout 176 for the integrated circuit system 12 including the scaffold interconnect network 100 and the integrated circuits. As illustrated, the package layout 176 may include a package substrate 102, a base die 104, two top dies 106, an intra-package bridge 112, an inter-package bridge 114, the scaffold interconnect network 100 including edges 108 positioned in a horizontal direction and in a vertical direction. The package layout 176 may also include integrated circuits that implement one or more functionalities from the library 168. For example, the package layout 176 may include a first integrated circuit 178 that performs compute functions, a second integrated circuit 180 that performs memory operations, a third integrated circuit 182 that performs input/output (I/O) operations, and/or a fourth integrated circuit 184 that performs protocol translation operations. While not illustrated in the package layout 176, the nodes 110 may include one or more functionalities. For example, the node functionalities may include 3D PHY, 2.5 PHY, security operations, and so on. It should be understood that the package layout 176 is exemplary, and the package layout 176 may include any suitable number of integrated circuits, functionalities, edges, nodes, and so on.

The processing circuitry may instruct a display to display the package layout 176. Additionally or alternatively, the processing circuitry may implement the package layout 176 onto the integrated circuit system 12, such as by transmitting a configuration bitstream to the integrated circuit system 12.

The method 150 includes various steps represented by blocks. Although the flowchart illustrates the acts in a certain sequence, it should be understood that the acts may be performed in any suitable order and certain acts may be carried out simultaneously, where appropriate. Further, certain steps or portions of the method 150 may be performed by separate systems or devices.

FIGS. 6A-G are schematic diagrams of the node 110 implementing different functionalities. The functionalities may be implemented via circuitry onto the nodes 110 during compiler runtime, and the functionality may be activated during system runtime. During compiler runtime, the compiler 20 may receive the connectivity graph 152 and generate the package layout based on FlexSCI guidelines and the connectivity graph 152. The compiler 20 may also validate a connection between two components, and instruct a display to display the indication. For example, security operations, such as validation operations, may be performed and a result of the validation may be displayed on a display of an electronic device. During system runtime, the package layout may be implemented onto the integrated circuit system 12. The schematic diagrams illustrated in FIGS. 6A-G are not mutually exclusive and may be used together to implement any suitable functionalities onto the node 110.

FIG. 6A illustrates a node 110 positioned between interconnects. Data, such as communication packets, may be transferred between components of the integrated circuit system 12, such as within the integrated circuit, between two more integrated circuits, the package substrate, the bridges and so on. As illustrated, the node 110 may be formed at an intersection of multiple interconnects. The node 110 may include four ports 210 to receive the data (e.g., data packets) via a first interconnect and/or transfer the data via a second interconnect.

FIG. 6B illustrates a node 110 that facilitates data pass throughs. For example, the node 110 of FIG. 6B may be formed by two interconnects physically coupled together by a metal component (e.g., silicon via). As illustrated, the node 110 includes a first input port 210A that receives data from a component via a first interconnect and a first output port 210B that outputs the data to another component via the first interconnect, for example. The node 110 may also include a second input port 210C that receives data from a component via a second interconnect and a second output port 210D that transfers the data to another component via the second interconnect. However, it should be understood that data may enter at any suitable port 210 and exit through any suitable port 210. Additionally or alternatively, the node 110 may include a switch to block data from entering a respective port 210 or block data from being transferred a respective port 210. The node 110 of FIG. 6B may be a passive node.

FIG. 6C illustrates a node 110 including a repeater and/or a retimer to adjust the data. The node 110 may be positioned on active silicon, and the node 110 may retime and/or rebuffer the data prior to transmitting the data. The retimer may receive a digital signal (e.g., data), recover timing information (e.g., clocking), and re-transmit an adjusted data signal (e.g., a re-timed version of the signal). The retimer may extract a clock from the digital signal and align the clock to compensate for losses and/or distortions that may be introduced by the interconnects. A repeater may extend a range of a digital signal by adjusting a power level of the signal. For example, the repeater may amplify the digital signal to a higher power to extend the range of communication by the digital signal.

FIG. 6D illustrates a node 110 including a protocol translator 220. The protocol translator 220 may convert data formats, data rates, and/or protocols used by a first component, such as a first integrated circuit, into those associated with a second component, such as a second integrated circuit, or vice versa. In another example, the protocol translator may convert data formats, data rates, and/or protocols used by a first interconnection resource (e.g., I/O block) within an integrated circuit into those associated with another component (e.g., programmable logic circuitry), or vice versa. As illustrated, for example, the node 110 may translate data in Universal Chiplet Interconnect Express (UCIe) protocols and/or Advanced eXtensible Interface (AXI) protocols to data in Bunches of Wires (BoW) protocols and/or Avalon Memory Mapped Interface (AWMM) protocols.

FIG. 6E illustrates a node 110 including communication interfaces, such as a transceiver PHY 240 and/or a raw data interface 242. The transceiver PHY 240 may convert digital data into electrical, optical, and/or radio frequency (RF) signals, or vice versa. The transceiver PHY 240 may also recover timing information from incoming data streams. The raw data interface 242 may transmit and/or receive unprocessed and/or minimally processed data without applying higher-level protocols, formatting, or interpretation. The node 110 may receive data from off-package components, for example, via the transceiver PHY 240 and route the data to another component within the integrated circuit system 12.

The interconnects forming the node 110 may also include switches 244 to facilitate input of data to the node 110 and output of data from the node 110. For example, the switch 244 may close to facilitate transfer of data into and/or out of the node 110, and the switch 244 may open to block transfer. As such, the node 110 may route data within the integrated circuit system 12 and to off-package components.

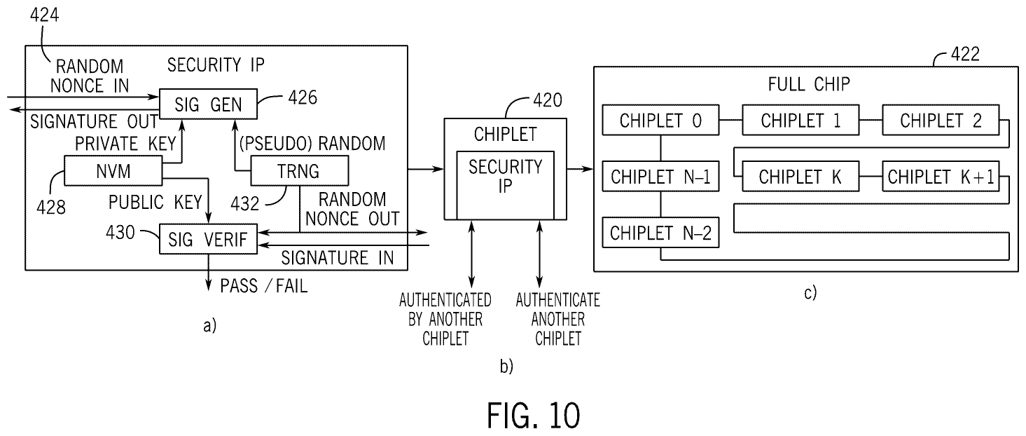

FIG. 6F illustrates a node 110 including security circuitry 260 and design for testing (DFT) circuitry 262. The security circuitry 260 may include a random number generator, a private/public key pair, signal verification circuitry, and so on, as described with respect to FIG. 10. Using the security circuitry 260, the node 110 may test and/or validate neighboring integrated circuits. The DFT circuitry 262 may facilitate testing and/or validation of components within the integrated circuit device after manufacturing and/or assembly to detect potential faults and/or defects. The DFT circuitry 262 may include specialized test structures and/or logic during design to facilitate efficient and/or thorough testing without full system activation. In certain embodiments, the node 110 may include built-in self-testing (BIST) circuitry to verify the functionality of components within the integrated circuit system 12, the functionality of the integrated circuit system 12, or any combination thereof. The BIST circuitry may also detect potential faults and/or defects. The node 110 may provide an indication of the validation, such as a passing validation or a failed validation, to an integrated circuit including the node 110. The integrated circuit may provide the indication to the data processing system 16, which may cause the indication to be displayed on a display. As such, the node 110 may facilitate testing and/or validation of integrated circuits within the integrated circuit system 12, after assembly and/or manufacturing.

As illustrated, the security circuitry 260 and DFT circuitry 262 may be communicatively coupled to a transceiver PHY 240 of the node 110 for data transfer. For example, the security circuitry 260 may transmit a random number for validating an integrated circuit via the transceiver PHY 240 and receive a signature from the integrated circuit via the transceiver PHY 240 to validate the device. As such, the node 110 may facilitate data transfer for the security operations.

FIG. 6G illustrates a node 110 including voltage regulator circuitry 280. The voltage regulator circuitry 280 may receive a voltage from a power rail and adjust the voltage to a target voltage level usable by a component within the integrated circuit, such as an integrated circuit that may be proximate to the node 110. By positioning voltage regulator circuitry 280 within the integrated circuit system 12, power delivery operations may be improved since a distance between the components and the voltage regulators may decrease. The power rail may be formed by a subset of wires from the “sea of wires.” That is, the compiler 20 may assign a power rail functionality to one or more interconnects. Additionally, the interconnects forming the node 110 may include switches (e.g., the switches 244 described with respect to FIG. 6E) that facilitate power delivery in the voltage regulator circuitry 280.

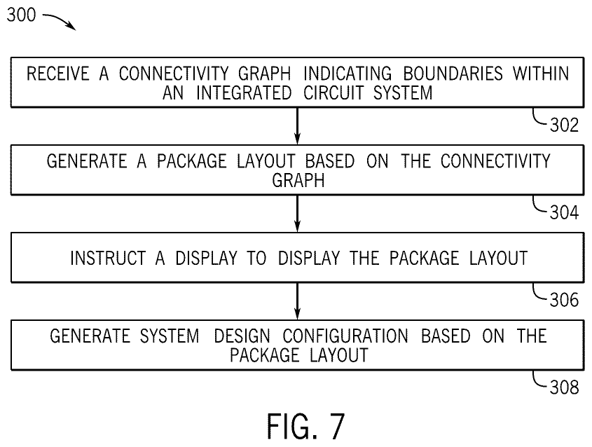

FIG. 7 is a flowchart of an example method 300 for generating a system design configuration 14 to implement on the integrated circuit system 12 based on a connectivity graph 152. The method 300 may be performed by the compiler 20, the design software 18, processing circuitry of the data processing system 16, or any combination thereof. The method 300 includes various acts represented by blocks. Although the flowchart illustrates the acts in a certain sequence, it should be understood that the acts may be performed in any suitable order and certain acts may be carried out simultaneously, where appropriate. Further, certain acts or portions of the method 300 may be performed by separate systems or devices.

At block 302, the processing circuitry may receive a connectivity graph 152 indicating one or more components for the integrated circuit system 12, boundaries within an integrated circuit system 12, functionalities of the integrated circuit system 12, and so on. The connectivity graph 152 may also illustrate split lines between each integrated circuit of the integrated circuit system 12 and between different packages of the integrated circuit system 12.

At block 304, the processing circuitry may generate a package layout 176 based on the connectivity graph 152. The processing circuitry may co-optimize the placement and routing of user logic and hierarchical network-on-chip (e.g., hierarchical AXI network-on-chip) based on the connectivity graph 152. For example, the processing circuitry may map valid networks to different communication protocols (e.g., no loops, traffic conflicts, or paths between disjoint graphs). The processing circuitry may pre-compile network management, such as router credits to minimize communication overheads after accounting for network hierarchy and protocol translation. The processing circuitry may implement circuitry for fault-tolerance to detect and repair failed connections without probe-based testing, including access and observability over multiple network hops, during compiler runtime and the circuitry may be activated to perform the operations during system runtime. The processing circuitry may abstract from input constraints to output system topology compatible with industry-standard design tools.

At block 306, the processing circuitry may instruct a display to display the package layout 176. As illustrated with respect to FIG. 4, the compiler may generate a package layout 176 that corresponds to the connectivity graph 152 that includes a scaffold interconnect network 100.

At block 308, the processing circuitry may generate a system design configuration based on the package layout 176. For example, the processing circuitry may generate a configuration bitstream based on the package layout 176 and transmit the configuration bitstream to the integrated circuit system 12 to implement the design onto the integrated circuit system 12. As such, the integrated circuit system 12 may perform the functionalities and operations indicated in the connectivity graph 152.

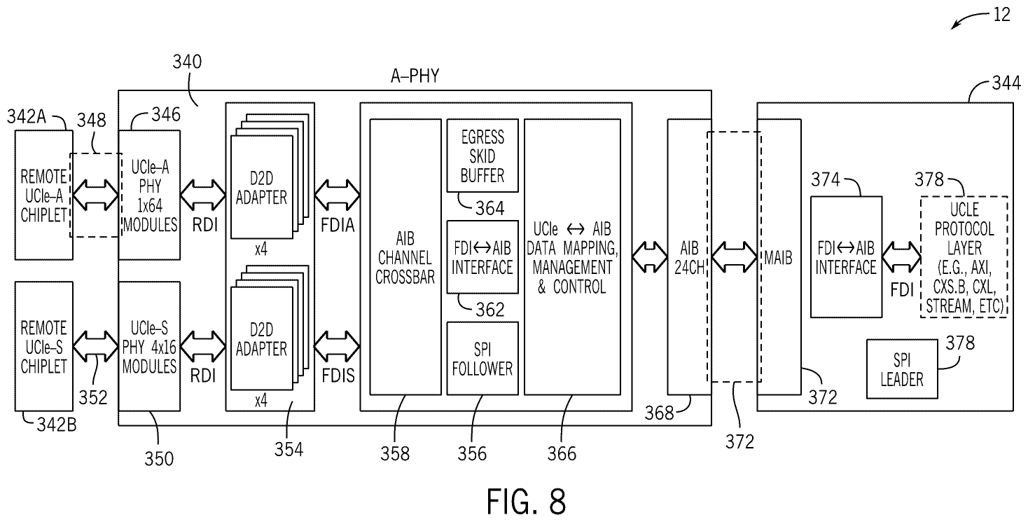

FIGS. 8-10 illustrate different embodiments of integrated circuits that implement circuitry from the library 168. The integrated circuits may be implemented into the integrated circuit system to provide functionality such as protocol translation, debugging operations, security operations, and so on. To this end, the compiler 20 may implement and/or overlay circuitry from the library 168 into and/or onto the integrated circuit. For example, to generate the integrated circuit, the compiler 20 may generate a system design configuration based on circuitry stored in the library 168 and implement the system design configuration onto the integrated circuit.

FIG. 8 is a schematic diagram of an example embodiment of an integrated circuit 340 that facilitates protocol translation. The integrated circuit 340 may be an adapter chiplet (e.g., integrated circuit, die) that bridges and/or translates data between different interfaces, protocols, and/or technologies. For example, the adapter chiplet may translate data from a first protocol to a second protocol, and vice versa. In another example, the adapter chiplet may translate data received from a first interface to data usable by a second interface, or vice versa. The adapter chiplet may facilitate protocol bridging, voltage and/or signal level translation, clock domain crossing, interface compatibility, and so on. In this way, the adapter chiplet may improve design flexibility.

In the illustrated example, the integrated circuit 340 may be an A-PHY Advanced Interface Bus (AIB) to Universal Chiplet Interconnect Express (UCIe) adapter chiplet. The integrated circuit 340 may couple to two UCIe chiplets 342 and an AIB chiplet 344. The integrated circuit 340 may receive data signals from a first UCIe chiplet 342A in UCIe-A protocols at a UCIe-A PHY port 346 via an interposer 348 and data signals from a second UCIe chiplet 342B in UCIe-S protocols at a UCIe-S PHY port 350 via package surface routing 352. The integrated circuit 340 may include D2D adapters 354 coupled to the UCIe ports 346, 350 to facilitate the transfer or transformation of data from one component to another. For example, the D2D adapters 354 may receive the data from the UCIe chiplets 342 and provide the data to a UCIe-to-AIB adapter block 358. The AIB channel crossbar 358 of the UCIe-to-AIB adapter block 356 may receive the data from the D2D adapters 354 and route the data to other components within the adapter block 356. For example, the AIB channel crossbar 358 may facilitate dynamic or static selection and mapping of AIB channels between different sources and destinations of the adapter block 356 and/or within the integrated circuit 340. The UCIe-to-AIB adapter block 356 may include components to facilitate protocol translation. The components may include a serial peripheral interface (SPI) follower 360, an FDI-AIB interface 362, an egress skid buffer 364, and a UCIe-AIB Data Mapping, Management, and Control Block 366. The UCIe-to-AIB adapter block 356 may provide the data in AIB protocols to an AIB port 368.

The integrated circuit 340 may be coupled to the AIB chiplet 344 via an interposer 370. The AIB chiplet 344 may include a advanced interface bus (AIB) port 372 to receive the data in AIB protocols from the integrated circuit 340. The AIB port 372 may provide the data to a Flit-aware Die-to-Die Interface (FDI) to AIB interface 374. The AIB chiplet 344 may also include an SPI leader 376 that initiates communication and transmits a clock signal and an UCIe protocol layer 378 that defines rules and conventions for data exchange between different integrated circuits, such as command sets, response formats, and flow control. The SPI leader 376 may select which follower to communicate with using a chip select. As such, the integrated circuit 340 and the adapter chiplet 344 may convert data from UCIe protocols to AIB protocols, or vice versa.

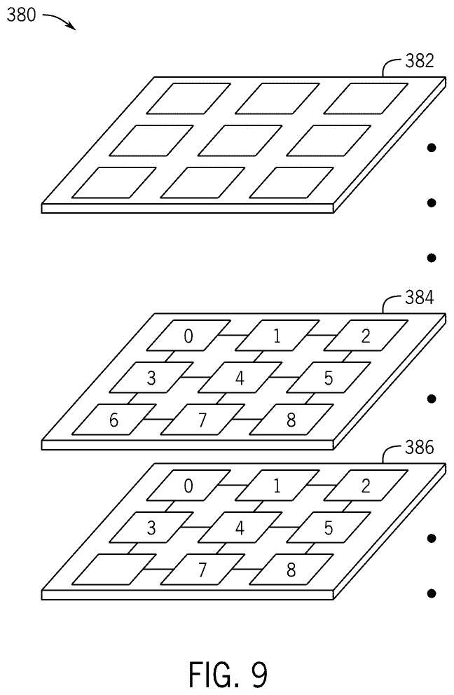

FIG. 9 is a schematic diagram of an example embodiment of an integrated circuit system 380 that facilitates debugging operations. The integrated circuit system 380 may include a first chiplet 382, a second chiplet 384, and a third chiplet 386 to perform the debugging operations. The first chiplet 382 may include a front end (FE) amplifier that receives a signal from another component of the integrated circuit system 12 for debugging. The FE amplifier may amplify the signal and sample and hold circuitry of the first chiplet 382 may maintain a voltage level of the signal for a period of time such that the signal may be processed and/or converted by an analog-to-digital converter (ADC) of the first chiplet 382. The second chiplet 384 may include memory to store the processed and/or converted signal from the first chiplet 382. The memory may store snapshots of system behavior, such as variables, register values, and/or intermediate data. The memory may store this data temporarily so that it may be analyzed by the third chiplet 386. The third chiplet 386 may include an FPGA and perform data analysis for the debugging operations. For example, the third chiplet 386 may retrieve and analyze the data stored in the memory of the second chiplet 384 for the debugging operations. The third chiplet 386 may transmit the output from the debugging operations to the compiler 20.

FIG. 10 is a schematic diagram of an example embodiment of an integrated circuit 420 that may facilitate security operations. The integrated circuit 420 may be a component within an integrated circuit system 422 that includes multiple integrated circuits in a daisy chain configuration to perform the security operations.

With the foregoing in mind, the integrated circuit 420 may implement security circuitry 424 to perform the security operations. The security circuitry 424 may include a signal generator 426, non-volatile memory 428 storing a public/private key pair, a signal verification block 430, and a random number generator 432. The signal generator 426 may authenticate the integrated circuit 420 based on based on a random nonce in, a private key from the non-volatile memory 428, and a random number from the random number generator 432. The signal verification block 430 may authenticate another integrated circuit that may be coupled to the integrated circuit 420 based on a received signature and a public key from the non-volatile memory 428.

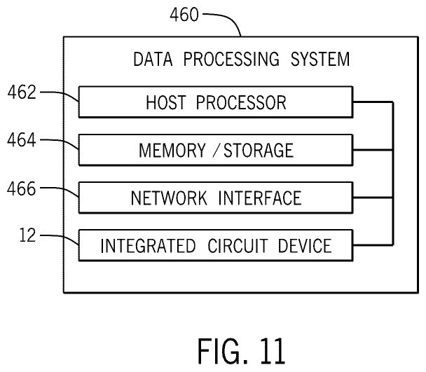

The processes discussed above may be carried out on the integrated circuit system 12, which may be a component included in a data processing system, such as a data processing system 460, shown in FIG. 11. The data processing system 460 may include the integrated circuit system 12, a host processor 462, memory and/or storage circuitry 464, and a network interface 466. The data processing system 460 may include more or fewer components (e.g., electronic display, user interface structures, application specific integrated circuits (ASICs)). The host processor 462 may include any of the foregoing processors that may manage a data processing request for the data processing system 460 (e.g., to perform elaboration and simulation, to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 464 may include random access memory (RAM), read-only memory (ROM), one or more hard drives, flash memory, or the like. The memory and/or storage circuitry 224 may hold data to be processed by the data processing system 460. In some cases, the memory and/or storage circuitry 464 may also store configuration programs (e.g., bitstreams, mapping function) for programming the integrated circuit system 12. The network interface 466 may allow the data processing system 460 to communicate with other electronic devices. The data processing system 460 may include several different packages or may be contained within a single package on a single package substrate. For example, components of the data processing system 460 may be located on several different packages at one location (e.g., a data center) or multiple locations. For instance, components of the data processing system 460 may be located in separate geographic locations or areas, such as cities, states, or countries.

The data processing system 460 may be part of a data center that processes a variety of different requests. For instance, the data processing system 460 may receive a data processing request via the network interface 466 to perform encryption, decryption, machine learning, video processing, voice recognition, image recognition, data compression, database search ranking, bioinformatics, network security pattern identification, spatial navigation, digital signal processing, or other specialized tasks.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A non-transitory, computer-readable medium including instructions that, when executed by processing circuitry, are to cause the processing circuitry to receive a plurality of definitions of multi-chip package components having scaffolds associated with a common scaffold definition and compiling a multi-chip package layout based on the scaffolds of the multi-chip package components.

EXAMPLE EMBODIMENT 2. The non-transitory, computer-readable medium of example embodiment 1, wherein the scaffolds are to implement a network-on-chip within the multi-chip package.

EXAMPLE EMBODIMENT 3. The non-transitory, computer-readable medium of example embodiment 1, wherein the instructions, when executed by the processing circuitry, are to cause the processing circuitry to activate a node formed by a subset of the scaffolds, wherein the node is positioned between a first component of the multi-chip package components and a second component of the multi-chip package components and configured to route data between the first component and the second component.

EXAMPLE EMBODIMENT 4. The non-transitory, computer-readable medium of example embodiment 3, wherein the instructions, when executed by the processing circuitry, is to cause the processing circuitry to implement protocol translation circuitry onto the node based on determining the first component uses a first protocol and the second component uses a second protocol different from the first protocol.

EXAMPLE EMBODIMENT 5. The non-transitory, computer-readable medium of example embodiment 1, wherein the instructions, when executed by the processing circuitry, are to cause the processing circuitry to identify a node of a first component of the multi-package components and implement security circuitry onto the node, wherein the node is to validate a second component communicatively coupled to the node.

EXAMPLE EMBODIMENT 6. The non-transitory, computer-readable medium of example embodiment 5, wherein the instructions, when executed by the processing circuitry, are to cause the processing circuitry to receive an indication of whether the second component is validated from the first node and instruct a display to display the indication.

EXAMPLE EMBODIMENT 7. The non-transitory, computer-readable medium of example embodiment 1, wherein the instructions, when executed by the processing circuitry, is to cause the processing circuitry to receive a connectivity graph including the plurality of definitions of the multi-chip packaging components and a set of split lines between components of a multi-chip package.

EXAMPLE EMBODIMENT 8. The non-transitory, computer-readable medium of example embodiment 1, wherein the instructions, when executed by the processing circuitry, is to cause the processing circuitry to implement the multi-chip package layout on an integrated circuit system including one or more integrated circuits, a package substrate, an interposer, or any combination thereof.

EXAMPLE EMBODIMENT 9. The non-transitory, computer-readable medium of example embodiment 1, wherein the scaffolds include a common pitch size.

EXAMPLE EMBODIMENT 10. A multi-die package including a first die including a first scaffolding including a first plurality of nodes along defined positions, a second die including a second scaffolding including a second plurality of nodes along defined positions, and a third die including third scaffolding including a third plurality of nodes aligned with the first plurality of nodes or the second plurality of nodes.

EXAMPLE EMBODIMENT 11. The multi-die package of example embodiment 10, wherein a first subset nodes of the first plurality of nodes are activated and a second subset of nodes of the first plurality of nodes are not activated.

EXAMPLE EMBODIMENT 12. The multi-die package of example embodiment 11, wherein the first subset of nodes is respectively coupled to a third subset of nodes of the third plurality of nodes to route data between the first die and the third die.

EXAMPLE EMBODIMENT 13. The multi-die package of example embodiment 10, wherein a node of the third plurality of nodes includes a router to route data between the first die and the second die, wherein the first die and the second die are mounted on top of the third die.

EXAMPLE EMBODIMENT 14. The multi-die package of example embodiment 10, including an interposer coupled to the third die and a fourth die, wherein the interposer includes a fourth scaffolding, and wherein the fourth die includes security circuitry.

EXAMPLE EMBODIMENT 15. The multi-die package of example embodiment 14, wherein the fourth die is to validate the first die, the second die, the third die, or any combination thereof.

EXAMPLE EMBODIMENT 16. A multi-chip package, including a first die including a first interconnect scaffold prescribed according to a common specification and a first node in a first placement and a second die including a second interconnect scaffold prescribed according to the common specification and a second node in a second placement, wherein the first node and the second node are communicatively coupled.

EXAMPLE EMBODIMENT 17. The multi-die package of example embodiment 16, wherein the first interconnect scaffold and the second interconnect scaffold have a common pitch size.

EXAMPLE EMBODIMENT 18. The multi-die package of example embodiment 16, including a third node positioned between the first node and the second node, wherein the third node includes a protocol translator to translate data to a first protocol used by the first die and a second protocol used by the second die.

EXAMPLE EMBODIMENT 19. The multi-die package of example embodiment 16, including a third node positioned between the first node and the second node, wherein the third node includes a retimer or a repeater to adjust data from the first node and transmit the adjusted data to the second node.

EXAMPLE EMBODIMENT 20. The multi-die package of example embodiment 16, wherein the first node includes voltage regulator circuitry to receive a voltage from a power rail of the multi-die package and adjust the voltage to a target voltage level usable by the first die.

What is claimed is:

1. A non-transitory, computer-readable medium comprising instructions that, when executed by processing circuitry, are to cause the processing circuitry to:
receive a plurality of definitions of components of a multi-chip package having scaffolds associated with a common scaffold definition; and
compiling a multi-chip package layout based on the scaffolds of the components.

2. The non-transitory, computer-readable medium of claim 1, wherein the scaffolds are to implement a network-on-chip within the multi-chip package.

3. The non-transitory, computer-readable medium of claim 1, wherein the instructions, when executed by the processing circuitry, are to cause the processing circuitry to:
activate a node formed by a subset of the scaffolds, wherein the node is positioned between a first component of the components and a second component of the components and configured to route data between the first component and the second component.

4. The non-transitory, computer-readable medium of claim 3, wherein the instructions, when executed by the processing circuitry, are to cause the processing circuitry to:
implement protocol translation circuitry onto the node based on determining the first component uses a first protocol and the second component uses a second protocol different from the first protocol.

5. The non-transitory, computer-readable medium of claim 1, wherein the instructions, when executed by the processing circuitry, are to cause the processing circuitry to:
identify a node of a first component of the components; and
implement security circuitry onto the node, wherein the node is to validate a second component communicatively coupled to the node.

6. The non-transitory, computer-readable medium of claim 5, wherein the instructions, when executed by the processing circuitry, are to cause the processing circuitry to:
receive an indication of whether the second component is validated from the node; and
instruct a display to display the indication.

7. The non-transitory, computer-readable medium of claim 1, wherein the instructions, when executed by the processing circuitry, are to cause the processing circuitry to:
receive a connectivity graph comprising the plurality of definitions of the components of the multi-chip package and a set of split lines between components of the multi-chip package.

8. The non-transitory, computer-readable medium of claim 1, wherein the instructions, when executed by the processing circuitry, are to cause the processing circuitry to:
implement the multi-chip package layout on an integrated circuit system comprising one or more integrated circuits, a package substrate, an interposer, or any combination thereof.

9. The non-transitory, computer-readable medium of claim 1, wherein the scaffolds comprise a common pitch size.

10. A multi-die package, comprising:
a first die comprising a first scaffolding comprising a first plurality of nodes along defined positions;
a second die comprising a second scaffolding comprising a second plurality of nodes along defined positions; and
a third die comprising third scaffolding comprising a third plurality of nodes aligned with the first plurality of nodes or the second plurality of nodes.

11. The multi-die package of claim 10, wherein a first subset nodes of the first plurality of nodes are activated and a second subset of nodes of the first plurality of nodes are not activated.

12. The multi-die package of claim 11, wherein the first subset of nodes is respectively coupled to a third subset of nodes of the third plurality of nodes to route data between the first die and the third die.

13. The multi-die package of claim 10, wherein a node of the third plurality of nodes comprises a router to route data between the first die and the second die, wherein the first die and the second die are mounted on top of the third die.

14. The multi-die package of claim 10, comprising an interposer coupled to the third die and a fourth die, wherein the interposer comprises a fourth scaffolding, and wherein the fourth die comprises security circuitry.

15. The multi-die package of claim 14, wherein the fourth die is to validate the first die, the second die, the third die, or any combination thereof.

16. A multi-chip package, comprising:
a first die comprising a first interconnect scaffold prescribed according to a common specification and a first node in a first placement; and
a second die comprising a second interconnect scaffold prescribed according to the common specification and a second node in a second placement, wherein the first node and the second node are communicatively coupled.

17. The multi-chip package of claim 16, wherein the first interconnect scaffold and the second interconnect scaffold have a common pitch size.

18. The multi-chip package of claim 16, comprising a third node positioned between the first node and the second node, wherein the third node comprises a protocol translator to translate data to a first protocol used by the first die and a second protocol used by the second die.

19. The multi-chip package of claim 16, comprising a third node positioned between the first node and the second node, wherein the third node comprises a retimer or a repeater to:
adjust data from the first node; and
transmit the adjusted data to the second node.

20. The multi-chip package of claim 16, wherein the first node comprises voltage regulator circuitry to receive a voltage from a power rail of the multi-chip package and adjust the voltage to a target voltage level usable by the first die.
